(19) United States
(12) Patent Application Publication
(10) Pub. No.: US 2012/0091461 A1
(43) Pub. Date: Apr. 19, 2012

(54) THIN FILM TRANSISTOR SUBSTRATE AND METHOD OF MANUFACTURING THE SAME

(76) Inventors: Joo-Han KIM, Yongin-si (KR); Wan-Soon Im, Cheonan-si (KR); Jae-Hak Lee, Seoul (KR); Se-Myung Kwon, Seongnam-si (KR); So-Young Koo, Bupyeong-gu (KR)

(21) Appl. No.: 13/219,379

(22) Filed: Aug. 26, 2011

(30) Foreign Application Priority Data
Oct. 19, 2010 (KR) 10-2010-0102106

(51) Int. Cl. H01L 29/786; H01L 21/336

(52) U.S. Cl. 257/66; 438/158; 257/E29.294; 257/E21.414

(57) ABSTRACT

A thin film transistor display substrate and a method of manufacturing the same are provided. The thin film transistor substrate includes a gate electrode formed on a display substrate, an active layer formed on the gate electrode to overlap with the gate electrode and including polycrystalline silicon, a first ohmic contact layer formed on the active layer, a second ohmic contact layer formed on the first ohmic contact layer, and a source electrode and a drain electrode each formed on the second ohmic contact layer.

### CROSS-REFERENCE TO RELATED APPLICATION

This application claims priority from Korean Patent Application No. 10-2010-0102106 filed on Oct. 19, 2010 in the Korean Intellectual Property Office, and all the benefits accruing therefrom under 35 U.S.C. 119, the contents of which in their entirety are herein incorporated by reference.

### BACKGROUND

1. Field of the Invention

Embodiments of the present invention relate generally to thin film transistors. More specifically, embodiments of the present invention relate to a thin film transistor substrate and a method of manufacturing the same.

2. Description of the Related Art

In one application, thin film transistors are used to independently actuate each pixel in a display device such as an organic light emitting diode or a liquid crystal display device.

A typical actuating and switching element of a conventional display device is an amorphous silicon thin film transistor (a-Si TFT). The amorphous silicon thin film transistor has an advantage of achieving relatively uniform device characteristics even on large-sized substrates. However, the amorphous silicon thin film transistor has relatively low electron mobility and low reliability, because device characteristics tend to degrade with continued operation. Accordingly, the use of amorphous silicon thin film transistors in organic light emitting displays (OLEDs) is challenging, as OLEDs typically operate under continuously flowing current.

Recently, this challenge, along with the demand for high-definition display quality, has led instead to the use of polycrystalline silicon thin film transistors (poly-Si TFTs), due to their superior performance relative to the amorphous silicon thin film transistor.

In the case of the a-Si TFT, in order to reduce contact resistance, n+ doped amorphous silicon (n+a-Si) is deposited on a semiconductor layer such that electrons can move without large loss. However, in the case of the poly-Si TFT, if an active layer is brought in contact with n+ doped amorphous silicon, the resulting electron barrier is excessively high and causes loss of electrons, thereby reducing on-current. Further, the poly-Si TFT has relatively high off-current compared to the a-Si TFT. Accordingly, in the poly-Si TFT, pixels remain charged to a certain degree even in their off state, which can result in inaccurate color representation. Therefore, it is desirable to both increase the on-current and reduce the off-current of poly-Si TFTs.

### SUMMARY

Embodiments of the present invention provide a thin film transistor substrate having increased on-current and reduced off-current relative to conventional poly-Si TFTs used in display substrates.

Embodiments of the present invention also provide a method of manufacturing such a thin film transistor substrate.

The objects of the present invention are not limited thereto, and the other objects of the present invention will be described in or be apparent from the following description.

According to an aspect of the present invention, there is provided a thin film transistor substrate including a gate electrode formed on a display substrate, and an active layer formed on the gate electrode to overlap with the gate electrode. The active layer includes polycrystalline silicon. The TFT substrate also includes a first ohmic contact layer formed on the active layer, a second ohmic contact layer formed on the first ohmic contact layer, and a source electrode and a drain electrode each formed on the second ohmic contact layer.

According to another aspect of the present invention, there is provided a method of manufacturing a thin film transistor substrate including forming a gate electrode on a display substrate, sequentially depositing, on the gate electrode, a gate insulating film, a polycrystalline silicon film, a doped first silicon film and a doped second silicon film, forming an active layer by patterning the polycrystalline silicon film, and forming first and second ohmic contact layers by patterning the doped first silicon film and the doped second silicon film so as to expose a portion of the active layer.

Other aspects of the present invention are included in the detailed description and drawings.

In the thin film transistor substrate in accordance with the embodiment of the present invention, a difference between the band gap of a contact layer and the band gap of an active layer is reduced, so as to increase electron mobility and on-current, thereby improving electrical characteristics of the thin film transistor.

In thin film transistor substrates made in accordance with embodiments of the present invention, leakage current and off-current decrease, so that colors can be represented more accurately on a display screen.

The effects of the present invention are not limited thereto, and various effects are included in the present specification.

### BRIEF DESCRIPTION OF THE DRAWINGS

The above and other aspects and features of the present invention will become more apparent by describing in detail exemplary embodiments thereof with reference to the attached drawings, in which:

FIG. 1 is a plan view showing a thin film transistor substrate including a thin film transistor in accordance with an embodiment of the present invention;

FIG. 2 is a cross sectional view taken along line I-I′ of FIG. 1;

FIG. 3 is a flowchart showing steps in a method of manufacturing a thin film transistor substrate in accordance with the embodiment of the present invention; and

FIGS. 4 to 10 are cross sectional views showing the sequential steps in the method of manufacturing a thin film transistor substrate in accordance with the embodiment of the present invention.

### DETAILED DESCRIPTION OF EMBODIMENTS

Advantages and features of the present invention and methods of accomplishing the same may be understood more readily by reference to the following detailed description of preferred embodiments and the accompanying drawings. The present invention may, however, be embodied in many different forms and should not be construed as being limited to the embodiments set forth herein. Rather, these embodiments are provided so that this disclosure will be thorough and complete and will fully convey the concept of the invention to those skilled in the art, and the present invention will only be defined by the appended claims. In the drawings, the size and relative sizes of layers and regions may be exaggerated for clarity.

It will be understood that when an element or a layer is referred to as being “on” or “connected to” another element or layer, it can be directly on or directly connected to the other element, or intervening elements may also be present. In contrast, when an element is referred to as being “directly on” or “directly connected to” another element, there are no intervening elements present. Like numbers refer to like elements throughout. As used herein, the term “and/or” includes any and all combinations of one or more of the associated listed items. Numerical values, as well as both the upper and lower bounds of ranges, are approximate.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation, in addition to the orientation depicted in the figures. Throughout the specification, like reference numerals in the drawings denote like elements.

Embodiments of the invention are described herein with reference to plan and cross-section illustrations that are schematic illustrations of idealized embodiments of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

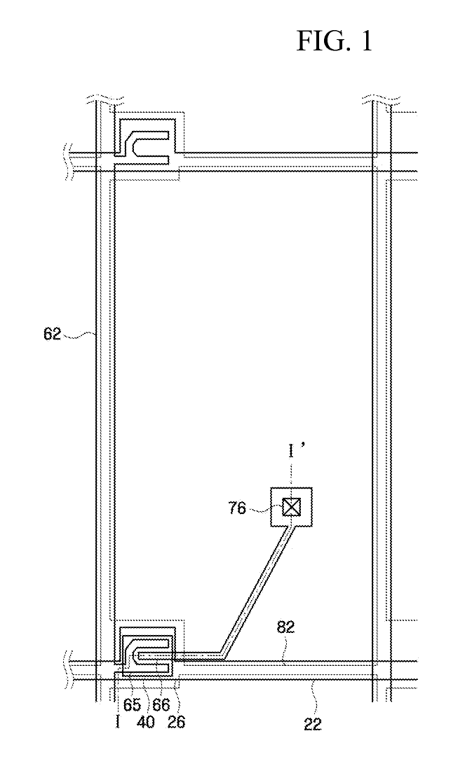

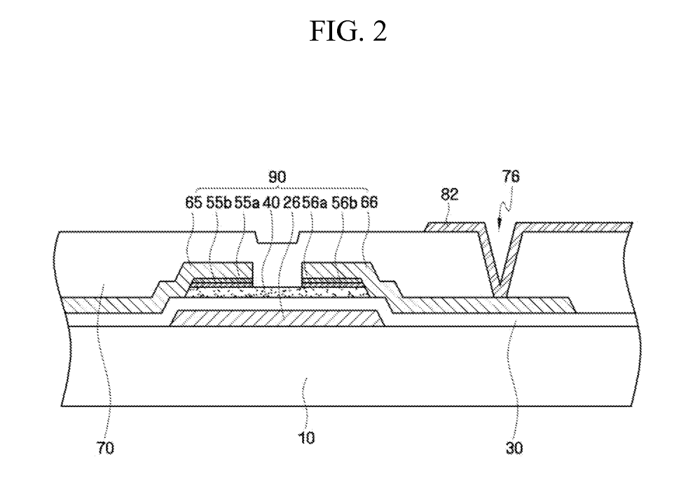

Hereinafter, a thin film transistor substrate in accordance with an embodiment of the present invention will be described with reference to FIGS. 1 and 2.

FIG. 1 is a plan view showing a thin film transistor substrate in accordance with an embodiment of the present invention. FIG. 2 is a cross sectional view of the thin film transistor substrate of FIG. 1, which is taken along line I-I′ of FIG. 1.

Referring to FIGS. 1 and 2, the thin film transistor substrate in accordance with this embodiment of the present invention includes an insulating substrate 10, a gate electrode 26, a gate insulating film 30, an active layer 40, a first ohmic contact layer 55a and 56a, a second ohmic contact layer 55b and 56b, a source electrode 65, a drain electrode 66, a passivation film 70, and a pixel electrode 82.

The insulating substrate 10 is formed of a transparent insulating material, e.g., glass or plastic. A gate line 22 and a data line 62 may be formed on the insulating substrate 10. The gate line 22 extends generally in a first direction, e.g., a horizontal direction, to transmit a gate signal. Further, the insulating substrate 10 may further include a sustain electrode (not shown) and a sustain electrode line (not shown) formed generally in parallel with the gate line 22. The data line 62 may be formed generally in a second direction, e.g., a vertical direction, to intersect the gate line 22 so as to thereby define a pixel. The gate line 22 and the data lines 62 may be formed of fire-resistant metal such as chromium (Cr), molybdenum-based metal, tantalum (Ta) and/or titanium (Ti). The gate line 22 and the data line 62 may have a multilayer structure including a lower film (not shown) formed of a fire-resistant metal or the like, and an upper film (not shown) disposed on the lower film and formed of a low resistivity material.

The gate electrode 26 may be formed on the insulating substrate 10. The gate electrode 26 may be connected to the gate line 22 and formed in a protruded shape, i.e. as a protrusion from the gate line 22. The gate electrode 26 may be formed of a metal such as any one or more of an aluminum-based metal such as aluminum (Al) and an aluminum alloy, silver-based metal such as silver (Ag) and a silver alloy, copper-based metal such as copper (Cu) and a copper alloy, molybdenum-based metal such as molybdenum (Mo) and a molybdenum alloy, chromium (Cr), titanium (Ti), tantalum (Ta) or the like. Further, the gate electrode 26 may have a multilayer structure including two conductive films (not shown) having different physical properties. One of the conductive films may be formed of a relatively low resistivity metal, e.g., aluminum-based metal, silver-based metal and copper-based metal, in order to reduce signal delay or voltage drop. The other one of the conductive films may be formed of a different material, e.g., molybdenum-based metal, chromium (Cr), titanium (Ti), tantalum (Ta) or the like, that has desirable contact characteristics with, particularly, indium tin oxide (ITO) and indium zinc oxide (IZO).

The gate insulating film 30 is formed on the gate line 22 and the gate electrode 26 to cover the gate line 22 and the gate electrode 26. The gate insulating film 30 may be formed of silicon nitride (SiNx), silicon oxide or the like. The gate insulating film 30 serves to reduce leakage current and increase mobility of electrons in the channel of a thin film transistor.

The active layer 40 can be formed of polycrystalline silicon on the gate insulating film 30 to overlap with the gate electrode 26.

When the active layer 40 is formed of polycrystalline silicon, it is possible to improve electric characteristics of the transistor, due to the higher electron mobility of polycrystalline silicon as compared to cases in which the active layer 40 is formed of amorphous silicon. Further, because polycrystalline silicon has an electron mobility of several tens to several hundreds of cm²/Vs, it is possible to provide transistor performance applicable to a high-definition display, and to improve the transistor's degradation characteristics.

The active layer 40 may be formed by depositing an amorphous silicon film by plasma enhanced chemical vapor deposition (PECVD), low pressure chemical vapor deposition (CVD) or the like, and then crystallizing the amorphous silicon film. The crystallization may be performed by using a well-known method in the art, e.g., laser annealing, solid phase crystallization, metal induced crystallization, or the like.

The active layer 40 may have various shapes, such as an insular shape and/or a linear shape. FIG. 2 illustrates a case where the active layer 40 is formed in an insular shape on the gate insulating film 30.

The first ohmic contact layer 55a and 56a is formed on the active layer 40, and the second ohmic contact layer 55b and 56b is formed on the first ohmic contact layer 55a and 56a. That is, the thin film transistor substrate in accordance with the embodiment of the present invention includes the ohmic contact layer having a double layer structure.

The first ohmic contact layer 55a and 56a and the second ohmic contact layer 55b and 56b include silicon, and the first ohmic contact layer 55a and 56a has higher crystallinity than the second ohmic contact layer 55b and 56b.

The first ohmic contact layer 55a and 56a may have a band gap smaller than that of the second ohmic contact layer 55b and 56b. In that case, a band gap difference between the active layer 40 and the first ohmic contact layer 55a and 56a is smaller than a band gap difference between the active layer 40 and the second ohmic contact layer 55b and 56b, thereby lowering an electron barrier. Consequently, electrons move more easily from the active layer 40 to the source electrode 65 or the drain electrode 66, so that both electron mobility and on-current increase. In this manner, configurations of the invention improve the electric characteristics of its transistors. In this case, the band gap means the energy difference between the top of the valance band and the bottom of the conduction band. The valance band is the highest range of electron energies in which electrons are normally present at absolute zero temperature, and the conduction band is the range of electron energies, higher than that of the valence band, sufficient to free an electron from binding with its individual atom and allow it to move freely within the atomic lattice of the material.

The band gap of the first ohmic contact layer 55a and 56a may be approximately 1.1 eV to 1.5 eV.

If the active layer 40 is formed of polycrystalline silicon, the band gap of the active layer 40 is about 1.1 eV. On the other hand, the band gap of amorphous silicon (a-Si) is equal to or greater than about 1.6 eV. That is, there is a band gap difference of about 0.5 eV or more between the active layer 40 and an amorphous silicon layer. Accordingly, if an amorphous silicon layer doped with impurities is formed on an active layer made of polycrystalline silicon, an electron barrier increases, reducing electron mobility. The band gap of the first ohmic contact layer 55a and 56a in accordance with this embodiment of the present invention ranges from about 1.1 eV to 1.5 eV, which is higher than the band gap of the active layer 40, but is lower than the band gap of amorphous silicon. Accordingly, the band gap difference between the active layer 40 and the first ohmic contact layer 55a and 56a is smaller than the band gap difference between the active layer 40 and the second ohmic contact layer 55b and 56b, thereby lowering the electron barrier. As a result, electron mobility increases and on-current increases, thereby improving electric characteristics of the transistor.

The first ohmic contact layer 55a and 56a may be formed of impurities-doped silicon including crystals.

Polycrystalline silicon and amorphous silicon have different lattice structures. Accordingly, if the active layer 40 is formed of polycrystalline silicon and the ohmic contact layer is formed of amorphous silicon having no crystallinity, a difference in lattice structure causes a difference in stress. Thus, on-current decreases and contact characteristics between films are reduced. However, in this embodiment, the first ohmic contact layer 55a and 56a is formed of doped silicon having crystallinity. Accordingly, there is less difference in lattice structure between the polycrystalline silicon forming the active layer 40 and the ohmic contact layer, thereby reducing loss of on-current.

The first ohmic contact layer 55a and 56a may also be formed of doped microcrystalline silicon.

The microcrystalline silicon (mc-Si) includes crystalline grains distributed in an amorphous matrix. The crystalline grains of microcrystalline silicon have a size typically on the order of several μm, which is very small compared to the crystalline grains of polycrystalline silicon. The microcrystalline silicon has a certain degree of crystallinity. Accordingly, a difference in lattice structure between the active layer's polycrystalline silicon and the ohmic contact layer becomes smaller, thereby reducing loss of on-current.

The second ohmic contact layer 55b and 56b may also be formed of n-type or p-type impurities-doped amorphous silicon.

When the active layer 40 is formed of polycrystalline silicon, the leakage current is about 100 times to 1000 times higher than the leakage current that occurs when the active layer 40 is formed of amorphous silicon. Accordingly, off-current increases and pixels are left charged in their off state, thereby failing to represent colors accurately. The off-current is affected by holes. The doped amorphous silicon of the second ohmic contact layer 55b and 56b has a relatively high band gap, to impede movement of holes. Accordingly, off-current decreases and colors can be represented more accurately.

The first ohmic contact layer 55a and 56a and the second ohmic contact layer 55b and 56b may have various shapes, such as an insular or island shape, and/or a linear shape. For example, if they are formed in an insular shape as shown in FIGS. 1-2, the first ohmic contact layer 55a and 56a and the second ohmic contact layer 55b and 56b may be positioned below the drain electrode 66 and the source electrode 65.

The source electrode 65 is formed on layers 55a and 55b, as well as the gate insulating film 30. The source electrode 65 is branched off from the data line 62 and extends to the top of the second ohmic contact layer 55b. The source electrode 65 at least partially overlaps the active layer 40.

The drain electrode 66 is formed on layers 56a and 56b, as well as the gate insulating film 30, to be separated from the source electrode 65 and opposite to the source electrode 65. The drain electrode 66 is formed to face the source electrode 65, with the gate electrode 26 interposed between the source electrode 65 and the drain electrode 66. The drain electrode 66 at least partially overlaps the active layer 40. The active layer 40 exposed between the source electrode 65 and the drain electrode 66 may include a channel in which electrons can relatively easily move.

The passivation film 70 is formed of an insulating film, and is formed on the data line 62, the source electrode 65, the drain electrode 66 and the exposed active layer 40. The passivation film 70 may be formed of an inorganic material such as silicon nitride, silicon oxide and the like, an organic material having desirable planarization characteristics and photosensitivity, or a low-k insulating material formed by plasma enhanced chemical vapor deposition (PECVD), such as a-Si:C:O and a-Si:O:F. Further, the passivation film 70 may have a double layer structure including a lower inorganic film and an upper organic film, in order to protect the exposed active layer 40 while using the excellent characteristics of the organic film. A contact hole 76 is formed in the passivation film 70 to expose the drain electrode 66.

The pixel electrode 82 is formed on the passivation film 70, and is electrically connected to the drain electrode 66 of the thin film transistor through the contact hole 76. That is, the pixel electrode 82 is physically and electrically connected to the drain electrode 66 through the contact hole 76, such that a data voltage can be applied to the pixel electrode 82 from the drain electrode 66. The pixel electrode 82 may be formed of a transparent conductive material, e.g., indium tin oxide (ITO) or indium zinc oxide (IZO). An alignment layer (not shown) may be coated on the pixel electrode 82 and the passivation film 70 to align liquid crystal molecules.

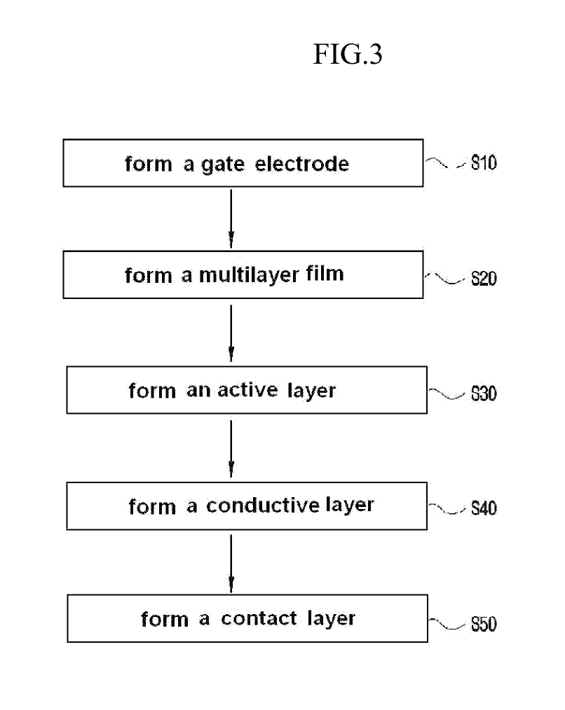

Hereinafter, a method of manufacturing a thin film transistor substrate in accordance with the embodiment of the present invention will be described in detail with reference to FIGS. 3 to 10.

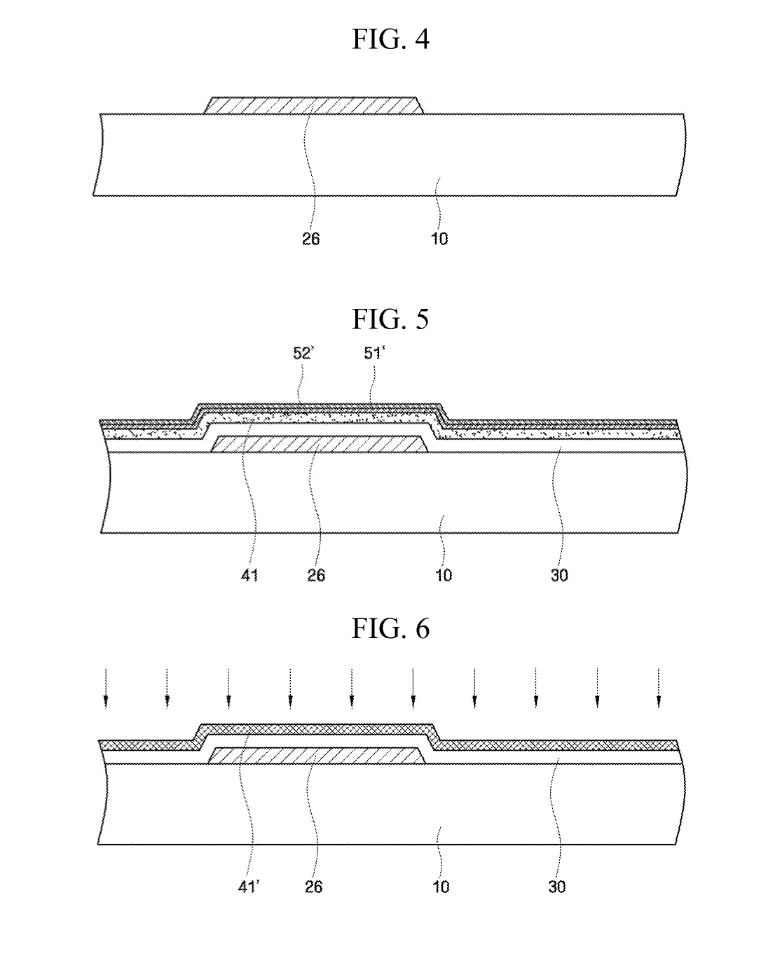

FIG. 3 is a flowchart showing steps in a method of manufacturing a thin film transistor substrate constructed in accordance with the above described embodiment of the present invention. FIGS. 4 to 10 are cross sectional views showing a sequence of steps in a method of manufacturing a thin film transistor substrate in accordance with the above described embodiment of the present invention.

Referring to FIG. 3, a method of manufacturing a thin film transistor substrate in accordance with this embodiment of the present invention includes forming a gate electrode S10, forming a multilayer film S20, forming an active layer S30, forming a conductive film S40, and forming a contact layer S50.

Forming the gate electrode S10 is one step in forming the gate electrode 26 on the substrate 10, as shown in FIG. 4.

Specifically, a metal layer is formed on the substrate 10 by, e.g., sputtering. The metal layer is then patterned by photolithography to form the gate electrode 26.

The substrate 10 may be an insulating substrate made of a material such as glass, quartz or plastic. The metal layer may be formed of aluminum-based metal such as aluminum (Al) and an aluminum alloy, silver-based metal such as silver (Ag) and a silver alloy, copper-based metal such as copper (Cu) and a copper alloy, molybdenum-based metal such as molybdenum (Mo) and a molybdenum alloy, chromium (Cr), titanium (Ti), tantalum (Ta) or the like.

Forming the multilayer film S20 one step in forming the gate insulating film 30, a polycrystalline silicon film 41, a doped first silicon film 51′, and a doped second silicon film 52′ on the gate electrode 26, as shown in FIG. 5.

Specifically, the gate insulating film 30 may be formed of an oxide film or nitride film. The polycrystalline silicon film 41, the doped first silicon film 51′ including crystals and the doped second silicon film 52′ are then sequentially deposited on the gate electrode 26 by a process such as plasma enhanced chemical vapor deposition (PECVD).

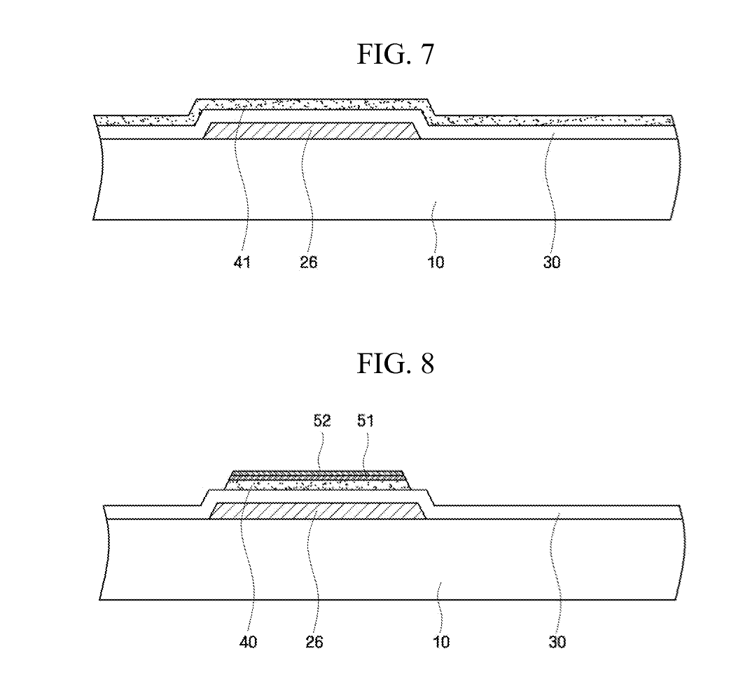

The polycrystalline silicon film 41 may be formed by directly depositing polycrystalline silicon, or by depositing amorphous silicon using a specific method and then crystallizing the amorphous silicon. The crystallization may be performed by using a well-known method. For example, as shown in FIGS. 6 and 7, an amorphous silicon film 41′ may be formed on the gate insulating film 30 by plasma enhanced chemical vapor deposition (PECVD) and annealed to form the polycrystalline silicon film 41. The annealing may be performed by using a laser (thus causing little or no damage to an organic substrate) or the like. Specifically, in laser annealing, a laser beam having locally high energy is irradiated on the amorphous silicon film 41′ as shown in FIG. 6. The amorphous silicon film 41′ is near-instantly heated by the laser beam to be melted into a liquid state. The melted amorphous silicon is crystallized into a solid phase to cause a phase transition, thereby forming polycrystalline silicon. Consequently, a polycrystalline silicon film 41 having relatively high electron mobility can be formed as shown in FIG. 7. In this case, because the energy of the irradiated laser beam is concentrated on only a top portion of the substrate, only a relatively small amount of thermal energy is transferred to the substrate. Accordingly, this process can also be used in conjunction with an organic substrate.

The doped first silicon film 51′ includes crystals and, specifically, may be formed of doped microcrystalline silicon. The microcrystalline silicon film may be formed of a thin film including crystalline grains with atoms arranged in a regular pattern, which may be obtained by a process similar to the above-described process of depositing amorphous silicon.

The doped microcrystalline silicon film may be formed by substantially simultaneously performing deposition and crystallization in the same equipment as the equipment for depositing the amorphous silicon. Specifically, the substrate is loaded into a CVD chamber and a silane gas (SiH₄) and a hydrogen gas (H₂) are injected into the chamber to perform the deposition. In this case, in order to substantially simultaneously perform deposition and crystallization, the hydrogen gas is supplied in an amount approximately 30 times larger than that of the silane gas. While the silane gas and the hydrogen gas injected into the chamber are decomposed by RF power and deposited, the silicon is converted from an amorphous state into a microcrystalline state having a regular lattice structure. Further, in order to increase crystallinity, the deposition and crystallization may be performed after forming a seed layer having fine silicon crystals. In this case, hydrogen atoms continuously collide with the deposited silicon layer to thereby break bonds between silicon and hydrogen atoms, and also to break bonds between weakly bonded silicon atoms. Accordingly, only a silicon layer with strongly bonded silicon atoms is] deposited. A microcrystalline silicon film doped with impurities may then be formed by supplying a phosphine gas (PH₃) or diborane gas (B₂H₆) into the CVD chamber.

The band gap of the doped first silicon film 51′ may range from about 1.1 eV to 1.5 eV. The band gap of the polycrystalline silicon film 41 is about 1.1 eV. Accordingly, if the band gap of the doped first silicon film 51′ ranges from 1.1 eV to 1.5 eV, a band gap difference with the polycrystalline silicon film 41 may be reduced, thus increasing electron mobility.

The doped second silicon film 52′ may be formed of amorphous silicon, where the band gap energy of the amorphous silicon is about 1.6 eV or more.

Forming the active layer S30 is, as shown in FIG. 8, one step in forming the active layer 40 by patterning the films disposed on the gate insulating film 30 after the multilayer film forming step S20.

Specifically, a photoresist film is formed on the doped second silicon film 52′ and exposed to light to form a photoresist pattern. Then, the polycrystalline silicon film 41, the doped first silicon film 51′ and the doped second silicon film 52′ are etched to thereby form the active layer 40 into an insular shape, a doped first silicon film pattern 51 having crystallinity, and a doped second silicon film pattern (doped amorphous silicon film pattern) 52. The etching may be performed by using known methods. Specifically, dry etching or the like may be performed. FIG. 8 illustrates the resulting active layer 40 having an insular shape, the doped first silicon film pattern 51 having crystallinity, and the doped amorphous silicon film pattern 52.

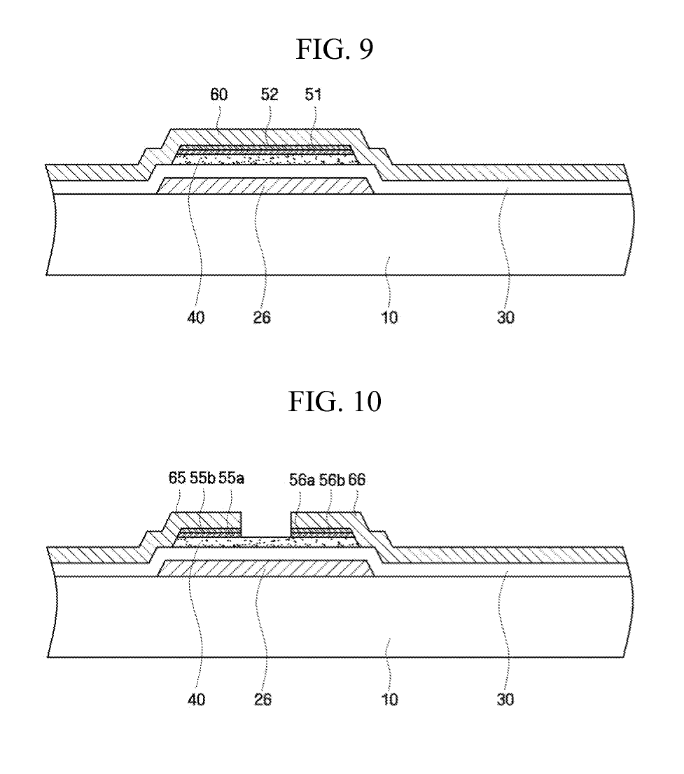

Forming the conductive film S40 is one step in forming a conductive film 60 on the doped amorphous silicon film pattern 52 as shown in FIG. 9.

Specifically, a metal layer is deposited on the doped second silicon film pattern 52 by, e.g., sputtering to form the conductive film 60. The metal layer is preferably formed of a fire-resistant metal such as chromium (Cr), molybdenum-based metal, tantalum (Ta) and titanium (Ti). The metal layer may have a multilayer structure including a lower film (not shown) formed of a fire-resistant metal or the like, and an upper film (not shown) disposed on the lower film and formed of a relatively low resistivity material.

Forming the contact layer S50 is one step in forming a contact layer by patterning the film positioned on the active layer 40 to expose a specific region of the active layer 40, as shown in FIG. 10.

Specifically, a photoresist film is coated on the doped first silicon film pattern 51, the doped second silicon film pattern 52 and the conductive film 60, and is exposed to light to form a photoresist pattern. Then, the conductive film 60 is etched to thereby form the source electrode 65 and the drain electrode 66. After forming the source electrode 65 and the drain electrode 66, the exposed doped first silicon film pattern 51 and the doped second silicon film pattern 52 are etched to form the first ohmic contact layer 55a and 56a and the second ohmic contact layer 55b and 56b, each being divided into two parts roughly centered over the gate electrode 26. The etching also exposes the active layer 40 through the first ohmic contact layer 55a and 56a and the second ohmic contact layer 55b and 56b. Oxygen plasma processing may be performed to stabilize the surface of the exposed active layer 40. The above etching can be accomplished by known operations.

In the method of manufacturing the thin film transistor substrate in accordance with the above described embodiment of the present invention, as described above, it is possible to manufacture a thin film transistor substrate that includes an active layer 40 formed of polycrystalline silicon, and an ohmic contact layer having a double layer structure with a first ohmic contact layer 55a and 56a formed of doped silicon containing crystals, and the second ohmic contact layer 55b and 56b formed of doped amorphous silicon. Further, in the above-described method, the thin film transistor substrate is manufactured such that the band gap of the first ohmic contact layer 55a and 56a is larger than the band gap of the active layer 40, and smaller than the band gap of the second ohmic contact layer 55b and 56b.

In the thin film transistor substrate in accordance with the above described embodiment of the present invention, the active layer 40 is formed of polycrystalline silicon to thereby increase the electron mobility and improve the degradation characteristics of the resulting transistor. Also, the first ohmic contact layer is formed of silicon, the silicon and polycrystalline silicon having a relatively small difference in band gap. Accordingly, it is possible to reduce loss of electrons during electron movement, and to increase the on-current of the transistor. Further, the second ohmic contact layer formed of amorphous silicon prevents holes from being injected into the source electrode and the drain electrode, thereby decreasing transistor off-current.

While the present invention has been particularly shown and described with reference to exemplary embodiments thereof, it will be understood by those of ordinary skill in the art that various changes in form and detail may be made therein without departing from the spirit and scope of the present invention as defined by the following claims. The exemplary embodiments should be considered in a descriptive sense only and not for purposes of limitation.

What is claimed is:

1. A thin film transistor substrate comprising:
a gate electrode formed on a display substrate;
an active layer formed on the gate electrode to overlap with the gate electrode, the active layer including polycrystalline silicon;
a first ohmic contact layer formed on the active layer;
a second ohmic contact layer formed on the first ohmic contact layer; and
a source electrode and a drain electrode each formed on the second ohmic contact layer.

2. The thin film transistor substrate of claim 1, wherein the first ohmic contact layer and the second ohmic contact layer each include silicon, and a band gap of the first ohmic contact layer is smaller than a band gap of the second ohmic contact layer.

3. The thin film transistor substrate of claim 2, wherein a band gap of the active layer is smaller than a band gap of the first ohmic contact layer.

4. The thin film transistor substrate of claim 3, wherein the band gap of the first ohmic contact layer is from approximately 1.1 eV to approximately 1.5 eV.

5. The thin film transistor substrate of claim 2, wherein the first ohmic contact layer has a crystallinity higher than that of the second ohmic contact layer.

6. The thin film transistor substrate of claim 5, wherein the first ohmic contact layer comprises doped microcrystalline silicon.

7. The thin film transistor substrate of claim 6, wherein the second ohmic contact layer comprises doped amorphous silicon.

8. The thin film transistor substrate of claim 1, wherein the first ohmic contact layer has a crystallinity higher than that of the second ohmic contact layer.

9. The thin film transistor substrate of claim 8, wherein the first ohmic contact layer comprises doped microcrystalline silicon.

10. The thin film transistor substrate of claim 8, wherein the second ohmic contact layer comprises doped amorphous silicon.

11. A method of manufacturing a thin film transistor substrate, comprising:
forming a gate electrode on a display substrate;
sequentially depositing, on the gate electrode, a gate insulating film, a polycrystalline silicon film, a doped first silicon film and a doped second silicon film;
forming an active layer by patterning the polycrystalline silicon film; and
forming first and second ohmic contact layers by patterning the doped first silicon film and the doped second silicon film so as to expose a portion of the active layer.

12. The method of claim 11, wherein a band gap of the first ohmic contact layer is larger than a band gap of the active layer, and is smaller than a band gap of the second ohmic contact layer.

13. The method of claim 12, wherein the band gap of the first ohmic contact layer is from approximately 1.1 eV to approximately 1.5 eV.

14. The method of claim 12, wherein said sequentially depositing further comprises forming the polycrystalline silicon film by depositing an amorphous silicon film on the gate insulating film and crystallizing the amorphous silicon film by annealing.

15. The method of claim 14, wherein the annealing is annealing with a laser beam.

16. The method of claim 11, wherein the first ohmic contact layer has a crystallinity higher than that of the second ohmic contact layer.

17. The method of claim 16, wherein the first ohmic contact layer comprises doped microcrystalline silicon.

18. The method of claim 16, wherein the second ohmic contact layer comprises doped amorphous silicon.

19. The method of claim 16, wherein said sequentially depositing further comprises forming the polycrystalline silicon film by depositing an amorphous silicon film on the gate insulating film and crystallizing the amorphous silicon film by annealing.

20. The method of claim 19, wherein the annealing is annealing with a laser beam.
